(19) United States
(12) Patent Application Publication
(10) Pub. No.: US 2024/0043654 A1
(43) Pub. Date: Feb. 8, 2024

(54) RESIN COMPOSITION FOR SEMICONDUCTOR PACKAGE AND RESIN COATED COPPER COMPRISING SAME

(71) Applicant: LG INNOTEK CO., LTD., Seoul (KR)

(72) Inventors: Byeong Kyun CHOI, Seoul (KR); Min Young HWANG, Seoul (KR); Moo Seong KIM, Seoul (KR); Jin Seok LEE, Seoul (KR)

(21) Appl. No.: 18/021,632

(22) PCT Filed: Aug. 17, 2021
(86) PCT No.: PCT/KR2021/010891

§ 371 Date: Feb. 16, 2023

(30) Foreign Application Priority Data
Aug. 25, 2020 (KR) 10-2020-0106822
Sep. 8, 2020 (KR) 10-2020-0114535
Sep. 8, 2020 (KR) 10-2020-0114565

(51) Int. Cl. C08K 3/22; C08K 3/34; H05K 1/03; H01L 23/498

(52) U.S. Cl. CPC C08K 3/22; C08K 3/34; H05K 1/036; H05K 1/0373; H01L 23/49894; H01L 23/49822; C08K 2003/2244; C08K 2003/2241; H05K 2201/0242; H05K 2201/0209; H05K 2201/0269

(57) ABSTRACT

A resin composition for a semiconductor package according to an embodiment includes a resin composition that is a composite of a resin and a filler disposed in the resin, wherein the filler includes at least one concave portion provided on a surface, wherein a content of the filler has a range of 10 vol. % to 40 vol % of a total volume of the resin composition, and wherein a porosity corresponds to a volume occupied by the concave portion in a total volume of the filler and has a range of 20% to 35%.

### CROSS-REFERENCE TO RELATED PATENT APPLICATIONS

This application is a U.S. National Stage Application under 35 U.S.C. § 371 of PCT Application No. PCT/KR2021/010891, filed Aug. 17, 2021, which claims priority to Korean Patent Application Nos. 10-2020-0106822, filed Aug. 25, 2020, 10-2020-0114535, filed Sep. 8, 2020 and 10-2020-0114565, filed Sep. 8, 2020, whose entire disclosures are hereby incorporated by reference.

### TECHNICAL FIELD

The embodiment relates to a resin composition for a semiconductor package, and in particular, to a resin composition for a semiconductor package having a low dielectric constant, and a resin coated copper (RCC), a copper clad laminate (CCL), and a circuit board comprising the same.

### BACKGROUND ART

A printed circuit board (PCB) is formed by printing a circuit line pattern on an electrically insulating substrate with a conductive material such as copper, and refers to a board immediately before mounting electronic components. That is, in order to densely mount many types of electronic devices on a flat plate, it means a circuit board on which a mounting position of each part is determined and a circuit pattern connecting the parts is printed on the flat plate surface and fixed.

Components mounted on the printed circuit board may transmit a signal generated from the component by a circuit pattern connected to each component.

On the other hand, recent portable electronic devices and the like are becoming highly functional, in order to perform high-speed processing of large amounts of information, high-frequency signals are being developed, and accordingly, there is a demand for a circuit pattern of a printed circuit board suitable for high-frequency applications.

The circuit pattern of the printed circuit board should minimize signal transmission loss and enable signal transmission without deteriorating the quality of the high-frequency signal.

The transmission loss of a circuit pattern of a printed circuit board mainly consists of a conductor loss due a metal thin film such as copper and a dielectric loss such as an insulating layer.

The conductor loss due to the metal thin film is related to a surface roughness of the circuit pattern. That is, as the surface roughness of the circuit pattern increases, transmission loss may increase due to a skin effect.

Accordingly, when the surface roughness of the circuit pattern is reduced, there is an effect of preventing a reduction in transmission loss, but there is a problem in that the adhesion between the circuit pattern and the insulating layer is reduced.

In addition, a material having a low dielectric constant may be used as an insulating layer of the circuit board in order to reduce a dielectric constant.

However, in the circuit board for high frequency applications, the insulating layer requires chemical and mechanical properties for use in the circuit board in addition to the low dielectric constant.

In details, it should have isotropy of electrical properties for ease of circuit pattern design and process, low reactivity with metal wiring materials, low ionic conductivity, sufficient mechanical strength to withstand processes such as chemical mechanical polishing (CMP), low moisture absorption, which can prevent delamination or increase in dielectric constant, heat resistance that can overcome the processing temperature, a low coefficient of thermal expansion to eliminate cracking due to temperature change, and furthermore, various conditions such as adhesion, crack resistance, low stress, and low high-temperature gas generation to minimize various stresses and peeling that may be generated at the interface with other materials must be satisfied.

In addition, the insulating layer used in the circuit board for high-frequency applications must satisfy various conditions such as an adhesion property that can minimize various stresses and peeling that can occur at interfaces with other materials (eg, metal thin films), a crack resistance property, a low stress property, a low high-temperature gas generation property.

Accordingly, the insulating layer used in the circuit board for high frequency use preferentially must have low dielectric constant and low thermal expansion coefficient properties, and accordingly, an overall thickness of the circuit board can be reduced.

However, when a circuit board is manufactured using an insulating layer of a low dielectric constant material that is thinner than a threshold, it causes reliability problems such as warping, cracking and delamination, and the reliability problems such as warping, cracking, and peeling increase as a number of layers of the insulating layer of the low dielectric constant material increases.

Accordingly, there is a demand for a method capable of implementing a fine circuit pattern while slimming a circuit board by using an insulating layer of a low dielectric constant material, and solving reliability problems such as warpage, cracking, and peeling.

### DISCLOSURE

### Technical Problem

The embodiment provides a resin composition for a semiconductor package with improved reliability, a resin coated copper (RCC) and a circuit board comprising the same.

In addition, the embodiment provides a resin composition for a semiconductor package having a low dielectric constant and a low coefficient of thermal expansion, a resin coated copper (RCC) and a circuit board comprising the same.

The technical problems to be achieved in the proposed embodiment are not limited to the technical problems mentioned above, and other technical problems not mentioned in the embodiments will be clearly understood by those of ordinary skill in the art to which the embodiments proposed from the description below.

### Technical Solution

A resin composition for a semiconductor package according to a first embodiment includes a resin composition that is a composite of a resin and a filler disposed in the resin, wherein the filler includes at least one concave portion provided on a surface, wherein a content of the filler has a range of 10 vol. % to 40 vol % of a total volume of the resin composition, and wherein a porosity corresponds to a volume occupied by the concave portion in a total volume of the filler and has a range of 20% to 35%.

In addition, a dielectric constant (Dk) of the resin by a combination of the resin and the filler is 2.5 or less.

In addition, the concave portion has a groove shape that does not pass through the filler.

In addition, the concave portion has a through hole shape passing through the filler.

In addition, the resin is formed of a modified epoxy or maleimide series.

In addition, the resin has a dielectric constant in a range of 2.3 to 2.5.

In addition, the filler includes a ceramic material of any one of SiO₂, ZrO₃, HfO₂, and TiO₂.

In addition, the filler has a dielectric constant in a range of 3.7 to 4.2.

In addition, the filler has a content in a range of 10 vol. % to 15 vol %, and the porosity has a range of 20% to 35%.

In addition, the filler has a content in a range of 15 vol. % to 30 vol %, and the porosity has a range of 30% to 35%.

In addition, the filler has a content in a range of 30 vol. % to 40 vol %, and the porosity has a range of 32% to 35%.

In addition, the resin includes a first region provided in a center, a second region provided on the first region, and a third region provided under the first region, and wherein a content of the filler in the first region is smaller than a content of the filler in each of the second region and the third region.

Meanwhile, an embodiment may provide a resin coated copper (RCC) prepared by laminating and compressing copper foil on one or both surfaces of the resin composition for the semiconductor package.

Meanwhile, a circuit board according to the embodiment includes a plurality of insulating layers; and a circuit pattern disposed on a surface of at least one insulating layer among the plurality of insulating layers; and a via passing through at least one insulating layer among the plurality of insulating layers; wherein at least one of the plurality of insulating layers includes the resin coated copper.

In addition, all of the plurality of insulating layers are formed of the resin coated copper.

In addition, the plurality of insulating layers includes a first insulating portion including at least one insulating layer; a second insulating portion disposed on the first insulating portion and including at least one insulating layer; and a third insulating portion disposed under the first insulating portion and including at least one insulating layer, wherein an insulating layer constituting the first insulating portion includes a prepreg, and an insulating layer constituting each of the second insulating portion and the third insulating portion includes the resin coated copper.

Meanwhile, a resin composition for a semiconductor package according to a second embodiment includes a resin composition that is a composite of a porous resin including a first pore and a porous filler disposed in the porous resin and including a second pore, wherein the porous filler has a content in a range of 30 vol. % to 40 vol % of a total volume of the resin composition, and at least one of a first porosity of the porous resin and a second porosity of the porous filler is in a range of 10% to 35%.

In addition, a dielectric constant (Dk) of the resin composition by a combination of the porous resin and the porous filler is 2.5 or less.

In addition, the second pore has a recess shape that does not pass through the porous filler.

In addition, the second pore has a through hole shape passing through the porous filler.

In addition, the porous resin is formed of a modified epoxy or maleimide series.

In addition, the porous resin has a dielectric constant (Dk) in a range of 2.3 to 2.5.

In addition, the porous filler includes a ceramic material of any one of SiO₂, ZrO₃, HfO₂, and TiO₂.

In addition, the porous filler has a dielectric constant (Dk) in a range of 3.7 to 4.2.

In addition, the first porosity of the porous resin has a range of 10% to 20%, and the second porosity of the porous filler has a range of 30% to 35%.

In addition, the first porosity of the porous resin has a range of 21% to 25%, and the second porosity of the porous filler has a range of 20% to 35%.

In addition, the first porosity of the porous resin has a range of 26% to 30%, and the second porosity of the porous filler has a range of 15% to 35%.

In addition, the first porosity of the porous resin has a range of 31% to 35%, and the second porosity of the porous filler has a range of 10% to 35%.

In addition, the second porosity of the porous filler has a range of 10% to 20%, and the first porosity of the porous resin has a range of 30% to 35%.

In addition, the second porosity of the porous filler has a range of 21% to 35%, and the first porosity of the porous resin has a range of 10% to 35%.

In addition, the resin includes a first region provided in a center, a second region provided on the first region, and a third region provided under the first region, and wherein the filler is disposed in the second region and the third region except for the first region.

Meanwhile, a resin composition for a semiconductor package according to a third embodiment includes a resin composition that is a composite of a porous resin including a first pore, a glass fiber disposed in the porous resin, and a porous filler disposed in the porous resin and including a second pore, wherein the porous filler has a content in a range of 20 vol. % to 30 vol % of a total volume of the resin composition, and at least one of a first porosity of the porous resin and a second porosity of the porous filler is in a range of 10% to 35%.

In addition, a dielectric constant (Dk) of the resin composition by a combination of the porous resin and the porous filler is 2.5 or less.

In addition, a content of the glass fiber has a range of 50 vol. % to 70 vol % of the total volume of the resin composition.

In addition, the second pore has a recess shape that does not pass through the porous filler or a through hole shape that passes through the porous filler.

In addition, the porous resin is formed of a modified epoxy or maleimide series.

In addition, the porous resin has a dielectric constant (Dk) in a range of 2.3 to 2.5.

In addition, the porous filler includes a ceramic material of any one of SiO₂, ZrO₃, HfO₂, and TiO₂.

In addition, the porous filler has a dielectric constant (Dk) in a range of 3.7 to 4.2.

In addition, the first porosity of the porous resin has a range of 10% to 20%, and the second porosity of the porous filler has a range of 30% to 35%.

In addition, the first porosity of the porous resin has a range of 21% to 25%, and the second porosity of the porous filler has a range of 20% to 35%.

In addition, the first porosity of the porous resin has a range of 26% to 30%, and the second porosity of the porous filler has a range of 15% to 35%.

In addition, the first porosity of the porous resin has a range of 31% to 35%, and the second porosity of the porous filler has a range of 10% to 35%.

In addition, the second porosity of the porous filler has a range of 10% to 20%, and the first porosity of the porous resin has a range of 30% to 35%.

In addition, the second porosity of the porous filler has a range of 21% to 35%, and the first porosity of the porous resin has a range of 10% to 35%.

### Advantageous Effects

The embodiment provides a resin composition for a semiconductor package constituting an insulating layer or an insulating film, which is a composite of resin and filler. In this case, the filler of the embodiment includes at least one concave portion provided on a surface. In addition, the embodiment controls a dielectric constant of the resin, a dielectric constant of the filler, a content of the resin, a content of the filler, and a ratio (eg, porosity) occupied by the concave portion in the filler. Accordingly, the embodiment may adjust the dielectric constant of the insulating layer or the insulating film to 2.5 Dk or less while maintaining a rigidity of the insulating layer or the insulating film, and accordingly, it is possible to provide a circuit board suitable for high-frequency signal transmission. In addition, the embodiment includes a concave portion in the filler, a degree of thermal expansion generated when the temperature of the filler is changed can be reduced by the concave portion, and thus the thermal strain of the insulating layer, which is a composite of the filler and the resin, can be improved.

Furthermore, the resin of the embodiment is a porous resin including a pore, and thus may include a first pore. The embodiment controls a dielectric constant of the resin, a dielectric constant of the filler, a content of the resin, a content of the filler, a porosity of the resin, and a porosity of the filler. Accordingly, the embodiment may adjust the dielectric constant of the insulating layer or the insulating film to 2.5 Dk or less while maintaining a rigidity of the insulating layer or the insulating film, and accordingly, it is possible to provide a circuit board suitable for high-frequency signal transmission.

Furthermore, the insulating layer or insulating film of the embodiment may be a prepreg. That is, the prepreg of the embodiment includes a resin and a glass fiber and fillers provided in the resin. The resin is a porous resin including a first pore. In addition, the filler includes a second pores of a through type or a non-through type. The embodiment controls a dielectric constant of the glass fiber, a dielectric constant of the resin, a dielectric constant of the filler, a content of the resin, a content of the filler, a content of the glass fiber, a porosity of the resin, and a porosity of the filler. Accordingly, the embodiment may adjust the dielectric constant of the insulating layer or the insulating film to 2.5 Dk or less while maintaining a rigidity of the insulating layer or the insulating film, and accordingly, it is possible to provide a circuit board suitable for high-frequency signal transmission.

Meanwhile, the resin composition in the embodiment may include a first region provided in a center, a second region provided on the first region, and a third region provided under the first region. In this case, the filler of the embodiment may be selectively disposed in the second region and the third region except for the first region. Alternatively, the filler of the embodiment may be disposed in the first to third regions. In this case, a content of the filler in the first region is smaller than a content of the filler in each of the second region and the third region. Accordingly, the embodiment can prevent an unintentional size expansion of the via hole in a process of de-smearing after forming a via hole in the insulating layer or insulating film, and accordingly, it is possible to form a fine via.

Accordingly, the embodiment can provide a highly reliable circuit board in which signal loss is minimized even in a high frequency band while the thickness of the circuit board is slimmed down by providing the insulating layer using a resin coated copper having a low dielectric constant.

### DESCRIPTION OF DRAWINGS

FIG. 1 is a view showing a resin coated copper according to a first embodiment.

FIG. 2 is a cross-sectional view showing a filler of FIG. 1 in detail.

FIG. 3 is a view showing a resin coated copper according to a modified example of FIG. 1.

FIG. 4 is a cross-sectional view showing a filler of FIG. 3 in detail.

FIGS. 5 (a) and (b) are views for explaining an arrangement structure of a filler in a resin coated copper according to an embodiment.

FIGS. 6 (a) and (b) are views showing a size change of a via hole according to a comparative example.

FIGS. 7 (a) and (b) are views showing a size change of a via hole according to an embodiment.

FIG. 8 is a view showing a resin coated copper according to a second embodiment.

FIG. 9 is a view showing a copper clad laminate including a composition for a semiconductor package according to a third embodiment.

FIG. 10 is a view showing a circuit board according to a first embodiment.

FIG. 11 is a view showing a circuit board according to a second embodiment.

FIG. 12 is a view showing a circuit board according to a third embodiment.

### DETAILED DESCRIPTION OF THE EMBODIMENTS

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and substituted for use.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art.

Further, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

In one embodiment, a resin composition for a semiconductor package may be a composite of a resin and a filler. For example, the resin composition for a semiconductor package according to an embodiment may include a resin and may have a structure in which a predetermined content of a filler is dispersed in the resin. In addition, in an embodiment, a copper foil layer may be laminated and pressed on at least one surface of the resin composition for the semiconductor package composed of a composite of the resin and the filler to manufacture a resin coated copper (RCC). Accordingly, the resin coated copper in one embodiment may include an insulating film (or insulating layer) composed of a composite of the resin and the filler and the copper foil layer laminated and compressed on at least one surface of the insulating film.

In another embodiment, a resin composition for a semiconductor package is a composite of a resin and a filler, and may have a structure in which a certain amount of filler and glass cloth are dispersed in the resin. Further, in another embodiment, a copper clad laminate (CCL: Copper Clad Laminate) may be manufactured by laminating and compressing a copper foil layer on at least one surface of the resin composition for the semiconductor package composed of a composite of the resin and the filler as described above. Accordingly, the copper clad laminate in another embodiment may include a copper foil layer laminated and compressed on at least one surface of a prepreg composed of a composite of resin, filler, and glass fiber.

Hereinafter, a resin composition for a semiconductor package according to an embodiment will be described. For example, the resin composition for the semiconductor package described below may refer to a resin composition for the semiconductor package applied to a resin coated copper (RCC). Specifically, hereinafter, a resin coated copper including an insulating film (or insulating layer) and a copper foil layer having a low dielectric constant and a low coefficient of thermal expansion according to an embodiment will be described.

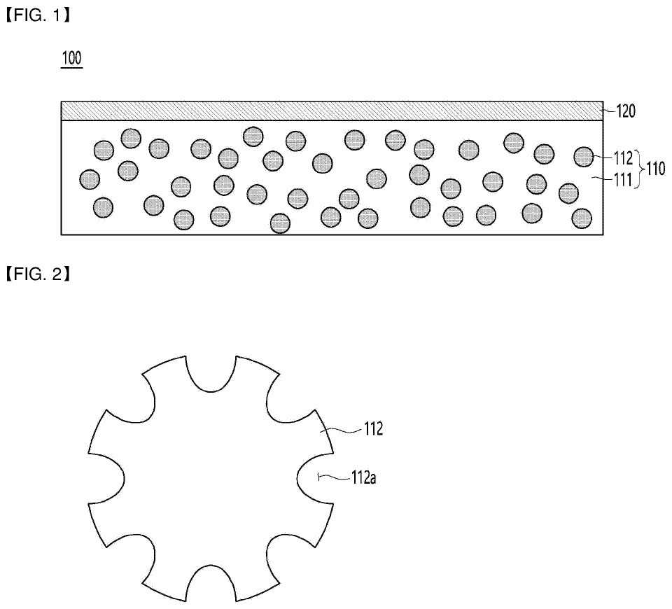

FIG. 1 is a view showing a resin coated copper according to a first embodiment, and FIG. 2 is a cross-sectional view showing a filler of FIG. 1 in detail.

Referring to FIGS. 1 and 2, the resin coated copper according to the first embodiment includes an insulating film (110, or an insulating layer or a resin composition for a semiconductor package) and a copper foil layer 120 disposed on one surface of the insulating film 110. The insulating film 110 may also be referred to as an insulating layer. Hereinafter, the insulating film will be described as the insulating layer 110 for convenience of explanation.

The insulating layer 110 includes a resin 111 and a filler 112 dispersed in the resin 111. The insulating layer 110 may be a resin for a semiconductor package. In an embodiment, a dielectric constant (Dk) of the insulating layer 110 can be adjusted to 2.5 or less through a change in a composition of the insulating layer 110 constituting the resin for the semiconductor package. Hereinafter, a resin for a semiconductor package is referred to as an insulating layer 110, and a resin composition for a semiconductor package corresponding to the insulating layer 110 will be described in detail.

The insulating layer 110 is a composite of a resin 111 and a filler 112. The insulating layer 110 may have a specific third dielectric constant due to a combination of a first dielectric constant of the resin 111 and a second dielectric constant of the filler 112.

In this case, the third dielectric constant Dk of the insulating layer 110 in the embodiment may be 2.5 or less. Accordingly, the insulating layer 110 in the embodiment can be applied to a circuit board suitable for high frequency applications. Accordingly, the insulating layer 110 in the embodiment can minimize signal loss and thereby improve reliability.

Hereinafter, properties of the resin 111 and the filler 112 for the insulating layer 110 to have the third dielectric constant Dk of 2.5 or less will be described in detail.

Before explaining this, an insulating layer in a comparative example will be described.

The insulating layer of the comparative example may include a resin and a ceramic filler disposed in the resin. The ceramic filler generally has a high dielectric constant. Specifically, a dielectric constant (Dk) of the ceramic filler having a lowest dielectric constant among types of ceramic filler is about 3.9. Accordingly, in the comparative example, there is a limit to lowering the dielectric constant of the insulating layer by changing the material of the filler.

In addition, the dielectric constant of the insulating layer of the comparative example is influenced by the dielectric constant of the resin as well as the dielectric constant of the ceramic filler. The dielectric constant (Dk) of the resin has a range of 2.2 to 6.5 depending on a type. In this case, a dielectric constant of polytetrafluoroethylene (PTFE) may have a low dielectric constant of about 2.2. However, polytetrafluoroethylene (PTFE: Polytetrafluoroethylene) requires a high process temperature, and it is difficult to apply to a 5G high frequency substrate as an additional insulating sheet (eg, bonding sheet) is additionally required in order to laminate multiple layers.

In general, the dielectric constant (Dk) of the resin of the insulating layer of the comparative example is about 2.4. Accordingly, the comparative example allows changing a prepreg type (PPG) to a resin coated copper type (RCC) by using an insulating layer without glass cloth, and thus, the dielectric constant (Dk) of the insulating layer is lowered to a level of 3.0. Furthermore, the comparative example reduces a content of a low dielectric constant resin and the filler dispersed in the low dielectric constant resin, and accordingly, the dielectric constant (Dk) of the insulating layer was reduced to a level of 2.8. However, when the content of the filler in the insulating layer is reduced, an overall strength of the insulating layer is reduced, resulting in a problem in that the manufacturing process of the circuit board does not proceed normally. Therefore, there is a limit to reducing the content of the filler in the insulating layer, and accordingly, the dielectric constant (Dk) of the insulating layer in the comparative example could not be lowered to 2.8 or less.

In contrast, the embodiment allows a resin 111 of the insulating layer 110 to have a low dielectric constant while allowing the filler 112 in the resin 111 to have a certain content or more, and accordingly, the filler 112 includes at least one concave portion 112a.

Preferably, a surface of the filler 112 in the embodiment is provided with a plurality of concave portions 112a concave inward. In this case, the plurality of concave portions 112a may be formed by being concaved to a certain depth in an inward direction from the surface of the filler 112. Preferably, the concave portion 112a is formed on the surface of the filler 112 and may be implemented in a groove shape that does not pass through the filler 112. Preferably, the filler 112 may be a porous filler including a plurality of concave portions 112a.

That is, the insulating layer 110 in a first embodiment may be a composite of a resin 111 and a porous filler 112 provided in the resin 111 and having at least one concave portion 112a on the surface.

On the other hand, although the filler 112 includes the concave potion 112a, it is not limited thereto. For example, the filler 112 may have a structure including a plurality of convex portions (not shown) protruding outward from the surface.

Accordingly, a porosity described below can be defined as follows.

Preferentially, when the filler 112 includes a concave portion, the concave portion 112a may be provided by forming a plurality of pores in the filler having a volume of “A”. In this case, the porosity may mean a ratio occupied by a volume of the concave portion 112a in the volume of “A” of the filler 112 having a circular shape.

In addition, when the filler 112 includes a convex portion, the porosity may be defined as follows. The filler 112 may have a circular shape. In addition, a plurality of convex portions may be provided on the filler. In this case, when the filler includes the convex portion, the porosity may be a ratio of a volume of an empty space in which the convex portion is not formed based on a volume of a circle corresponding to a total diameter of the filler including the convex portion.

Meanwhile, the porosity of the filler may also be expressed as oil absorption amount (ml/100 g, LP). That is, assuming that the filler has a perfect spherical shape, oil can be penetrated into the filler. Also, a penetration amount of the oil may correspond to the volume of the empty space in the total volume of the filler having the spherical shape. Accordingly, the porosity can also be expressed as the oil absorption amount.

Alternatively, the porosity of the filler may be measured through a gas adsorption method (BET) or a mercury adsorption method. The gas adsorption method is a method of adsorbing a gas (generally, nitrogen) on a sample to measure a specific surface area, a pore size and a distribution of the sample surface, and it can analyze even closed micropores. A pore size analysis range of this gas adsorption method is 0.35 nm to 200 nm, and as a result of this analysis, surface area (m2/g) pore size, total pore volume, and pore size distribution can be confirmed.

The gas adsorption method allows the surface area of the sample surface to be calculated using the change in the volume of the adsorbed gas according to the change in pressure. In addition, the shape of the pores present in the sample can be confirmed according to a curve shape of a gas adsorption/desorption graph that can be confirmed by the gas adsorption method.

The resin 111 in the first embodiment may have a low dielectric constant.

In this case, a type of general resin and a dielectric constant according to the type of resin are shown in table 1.

TABLE 1

| | | | Maleimide | | |
|---|---|---|---|---|---|
| | | | or modify | | |
| material | Phenolic | Epoxy | epoxy | Cyanate | PTFE |
| dielectric | 4.5~6.5 | 3.5~5.0 | 2.3~2.5 | 2.6~3.0 | 2.2 |
| constant | | | | | |
| (Dk) | | | | | |

As described above, the resin may include various materials. At this time, the resin including phenolic, general epoxy, and cyanate has a dielectric constant (Dk) of 2.6 or more, and accordingly, it is difficult to lower the dielectric constant (Dk) of the insulating layer 110 to 2.5 or less.

In addition, the resin containing PTFE has a low dielectric constant of about 2.2, but a high process temperature condition is required. For example, a normal resin requires a processing temperature of 250° C., but the PTFE requires a processing temperature of 300° C. or more. In addition, a bonding sheet is essentially required during the lamination process in order to manufacture a multi-layered circuit board of the PTFE, and thus an overall thickness of the circuit board increases, resulting in a problem in slimming the circuit board.

Accordingly, the embodiment allows the dielectric constant of the resin 111 of the insulating layer 110 to be lowered by using a modified epoxy or a maleimide series.

That is, the resin 111 of the embodiment may include a modified epoxy or a maleimide series resin having a dielectric constant (Dk) in a range of 2.3 to 2.5.

The dielectric constant Dk of the filler 112 may have a certain level. For example, the filler 112 may be formed of a ceramic filler. In this case, the dielectric constant (Dk) according to a type of ceramic filler is shown in Table 2 below.

TABLE 2

| material | SiO₂ | Al₂O₃ | ZrO₃ | HfO₂ | TiO₂ |
|---|---|---|---|---|---|
| dielectric | 3.7~4.2 | 9.0 | 3.7~4.2 | 3.7~4.2 | 3.7~4.2 |
| constant | | | | | |
| (Dk) | | | | | |

As described above, when the filler 112 is formed of Al₂O₃, the dielectric constant (Dk) of the filler 112 is 9.0, and accordingly, there is a limit to lowering a total the dielectric constant (Dk) of the insulating layer 110, which is a composite thereof, to 2.5 or less only with the dielectric constant of the resin 111.

Therefore, the filler 112 of the embodiment is formed using any one ceramic material from SiO₂, ZrO₃, HfO₂, and TiO₂.

Accordingly, a dielectric constant of the filler 112 may have a range of 3.7 to 4.2 Dk. In this case, the dielectric constant of the filler 112 may mean the dielectric constant in a state in which a concave portion 112a is not provided in the filler 112. Specifically, when the filler 112 is basically formed of any one ceramic material from SiO₂, ZrO₃, HfO₂, and TiO₂, it may have a dielectric constant in a range of 3.7 to 4.2 Dk.

In this case, the filler 112 may have a concave portion 112a as described above. Specifically, the concave portion 112a of the filler 112 in the first embodiment may be formed by being concaved into the surface of the filler 112. More specifically, the concave portion 112a of the filler 112 in the first embodiment has a depth smaller than a diameter of the filler 112 and may be concaved into the filler 112. More specifically, the concave portion 112a of the filler 112 may be a groove or a recess formed on the surface of the filler 112 and concaved into the interior of the filler 112.

Accordingly, there is a limit to only adjusting the materials and contents of the resin 111 and the filler 112 in order for the insulating layer 110 to have a dielectric constant of 2.5 or less. Therefore, in the embodiment, the concave portion 112a is provided in the filler 112 so that the insulating layer 110 formed of a combination of the resin 111 and the filler 112 has a dielectric constant Dk of 2.5 or less.

In this case, the dielectric constant of the insulating layer 110 may be determined by a dielectric constant of the resin 111, a dielectric constant of the filler 112, a content of the resin 111, a content of the filler 112, and a ratio of the volume occupied by the concave portion 112a to a total volume of the filler 112.

As described above, the resin 111 is formed of a modified epoxy or maleimide series, and accordingly, it may include a modified epoxy or maleimide series having a dielectric constant (Dk) in the range of 2.3 to 2.5.

In addition, the filler 112 may include a ceramic material of any one SiO₂, ZrO₃, HfO₂, and TiO₂, and may have a dielectric constant (Dk) in a range of 3.7 to 4.2.

On the other hand, when the filler 112 is included in less than 10 vol. % in the insulating layer 110, a stiffness of the insulating layer 110 is weakened, and accordingly, a reliability problem may occur during the manufacturing process of the circuit board. For example, when the filler 112 is included in less than 10 vol. % in the insulating layer 110, a degree of warping of the insulating layer 110 becomes severe during the manufacturing process of the circuit board, and accordingly, a problem in which a normal manufacturing process cannot proceed may occur.

In addition, when the filler 112 exceeds 40 vol. % in the insulating layer 110, it may be difficult to match the dielectric constant (Dk) of the insulating layer 110 to 2.5 or less. For example, when the filler 112 exceeds 40 vol. % in the insulating layer 110, a volume occupied by the concave portion 112a in a total volume of the filler 112 should be increased in order to adjust the dielectric constant (Dk) of the insulating layer 110 to 2.5 or less, as a result, the stiffness of the filler 112 is weak, and thus reliability problems may occur.

Accordingly, a content of the filler 112 has a range of 10 vol. % to 40 vol. % in the insulating layer 110. Correspondingly, a content of the resin 111 has a range of 60 vol. % to 90 vol. % in the insulating layer 110.

Meanwhile, the porosity, which is the ratio of the volume occupied by the concave portion 112a to the total volume of the filler 112, may vary depending on the content of the filler 112. For example, when the content of the filler 112 increases, the porosity may increase in proportion to the content of the filler 112. In addition, when the content of the filler 112 decreases, the porosity also may decrease. However, when the porosity, which is the ratio occupied by the concave portion 112a in the total volume of the filler 112, exceeds 35%, the stiffness of the filler 112 and the strength of the insulating layer 110 as a composite thereof is weakened, which can cause reliability problems. In addition, when the porosity, which is the ratio occupied by the concave portion 112a in the total volume of the filler 112, is less than 20%, it may be difficult to set the dielectric constant Dk of the insulating layer 110 to 2.5 or less.

Therefore, the porosity, which is the ratio of the volume occupied by the concave portion 112a to the total volume of the filler 112 in the embodiment, is set to have a range of 20% to 35%. However, the ratio occupied by the concave portion 112a may be accurately determined by the content of the filler 112 in the insulating layer 110.

Specifically, the dielectric constant of the insulating layer 110 according to the ratio of the content of the filler 112 in the insulating layer 110 and the concave portion 112a in the filler 112 may be as shown in Table 3 below.

TABLE 3

| filler | | porosity of groove-shaped concave portion | | | | | | |
|---|---|---|---|---|---|---|---|---|
| contents | | (porosity, %) | | | | | | |
| (Vol. %) | | | 0 | 0 | 5 | 0 | 5 | 0 |
| 10 | dielectric | .6 | .55 | .50 | .49 | .47 | .46 | .45 |
| | constant | | | | | | | |
| 20 | dielectric | .74 | .65 | .57 | .53 | .49 | .47 | .46 |
| | constant | | | | | | | |
| 30 | dielectric | .9 | .75 | .63 | .57 | .50 | .48 | .47 |
| | constant | | | | | | | |
| 40 | dielectric | .08 | .85 | .69 | .61 | .53 | .49 | .48 |
| | constant | | | | | | | |

Referring to Table 3, the ratio occupied by the concave portion 112a in the total volume of the filler 112 may be defined as porosity.

In this case, when a content of the filler 112 is 10 vol. % in the insulating layer 110, the porosity of the filler 112 should be 20% or more. However, when the porosity exceeds 35%, a reliability problem may occur due to stiffness as described above. Accordingly, in the embodiment, when a content of the filler 112 is 10 vol. % in the insulating layer 110, the porosity of the filler 112 may be 20% to 35%. For example, when a content of the filler 112 has a range of 10 vol. % to 15 vol. % in the insulating layer 110, the porosity of the filler 112 may be 20% to 35%.

In addition, when a content of the filler 112 is 20 vol. % in the insulating layer 110, the porosity of the filler 112 should be 30% or more. However, when the porosity exceeds 35%, a reliability problem may occur due to stiffness as described above. Accordingly, in the embodiment, when a content of the filler 112 is 20 vol. % in the insulating layer 110, the porosity of the filler 112 may be 30% to 35%. For example, when a content of the filler 112 has a range of 15 vol. % to 30 vol. % in the insulating layer 110, the porosity of the filler 112 may be 30% to 35%.

In addition, when a content of the filler 112 is 40 vol. % in the insulating layer 110, the porosity of the filler 112 should be 35% or more. However, when the porosity exceeds 35%, a reliability problem may occur due to stiffness as described above. Accordingly, in the embodiment, when a content of the filler 112 is 40 vol. % in the insulating layer 110, the porosity of the filler 112 may be 35%. For example, when a content of the filler 112 exceeds 30 vol. % in the insulating layer 110 and is 40 vol. % or less in the insulating layer 110, the porosity of the filler 112 may be 32% to 35%.

As described above, the embodiment allows the dielectric constant Dk of the insulating layer 110, which is a composite of the resin 111 and the filler 112, to have 2.5 or less by adjusting the dielectric constant of resin 111, the dielectric constant of the filler 112, the content of the resin 111, the content of the filler 112 and the ratio occupied by the concave portion in the filler 112.

Meanwhile, the dielectric constant of the insulating layer 110 may be measured through the following equipment and methods. That is, the insulating layer 110 is not used as a single product, but can be used as a resin coated copper in which a copper foil layer 120 is laminated on at least one surface thereof. In this case, the dielectric constant of the insulating layer 110 may be measured by proceeding with a process of removing the copper foil layer 120 from the resin coated copper, a process of drying the insulating layer 110 at 100° C. for 60 minutes in a state where the copper foil layer 120 is removed, and a process of measuring this using a resonator using an N5222A PNA Network analyzer (Agilent) device under conditions of 25° C. and 50% RH by a split post dielectric resonance (SPDR) method.

According to this, in the embodiment, the dielectric constant (Dk) of the insulating layer 110 can be adjusted to 2.5 or less while maintaining the rigidity of the insulating layer 110, thereby providing a circuit board suitable for high-frequency signal transmission. In addition, in the embodiment, the concave portion 112a is provided in the filler 112, and the degree of thermal expansion generated when the temperature of the filler 112 is changed can be reduced by the concave portion 112a. A thermal strain of the insulating layer, which is a composite of the filler and the insulating layer, can be improved.

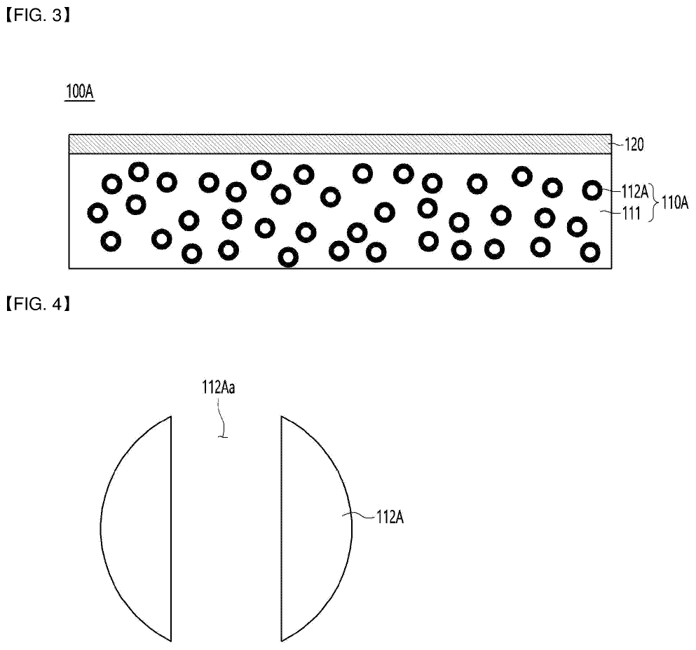

FIG. 3 is a view showing a resin coated copper according to a modified example of FIG. 1, and FIG. 4 is a cross-sectional view showing a filler of FIG. 3 in detail.

Referring to FIGS. 3 and 4, the resin coated copper according to a modified embodiment includes an insulating layer 110A and a copper foil layer 120 disposed on one surface of the insulating layer 110A. The insulating layer 110A includes a resin 111 and a filler 112A dispersed in the resin 111.

The filler 112A in the modified embodiment includes a plurality of concave portions 112Aa concave inwardly on the surface. In this case, the plurality of concave portions 112Aa may be formed by being concaved to a certain depth in an inward direction from the surface of the filler 112. Preferably, the concave portion 112Aa is formed on the surface of the filler 112A and may be implemented in the form of a hole passing through the filler 112A. Preferably, the filler 112A may be a hollow filler including at least one concave portion 112Aa. That is, the concave portion 112Aa of the filler 112A in the modified embodiment may be a through hole passing through the surface of the filler 112A, unlike the concave portion of FIG. 1.

Specifically, the concave portion of the filler in FIG. 1 has a recess shape of a non-penetrating structure, but the concave portion of the filler in FIG. 3 may have a through hole shape of a penetrating structure. That is, the insulating layer 110A in FIG. 3 may be a composite of the resin 111 and the hollow filler 112A formed in the resin 111 and including at least one concave portion 112Aa on the surface.

In this case, the dielectric constant of the insulating layer 110A in FIG. 3, which is a composite of the filler 112A and the resin 111, may change based on the ratio occupied by the through hole-shaped concave portion 112Aa in the filler 112A. That is, the dielectric constant of the insulating layer 110A may be determined by the dielectric constant of the resin 111, the dielectric constant of the filler 112A, the content of the resin 111, the content of the filler 112A, and a ratio of the volume occupied by the concave portion 112Aa to a total volume of the filler 112A. In this case, the ratio of the volume occupied by the concave portion 112Aa to the total volume of the filler 112A may also be expressed as porosity.

In other words, the concave portion have a groove shape or a through hole shape in a generally porous filler. Specifically, a plurality of concave portion may have a closed groove shape in which a plurality of concave portions are separated or isolated from each other in the filler. In addition, the concave portion may have an open-type hole shape in which a plurality of concave portion are connected to each other in the filler. In addition, the concave portion 112a in the first embodiment may be configured in a closed form within the filler, and the concave portion 112Aa in the second embodiment may be configured in an open form within the filler 112A.

Meanwhile, the porosity corresponding to the ratio of the volume occupied by the concave portion 112Aa to the total volume of the filler 112A may vary depending on the content of the filler 112A. For example, when the content of the filler 112A increases, the porosity, which is a ratio of the volume occupied by the concave portion 112Aa, may increase in proportion to the content of the filler. In addition, when the content of the filler 112A decreases, the ratio of the volume occupied by the concave portion 112Aa also may decrease. However, when the ratio occupied by the concave portion 112Aa in the total volume of the filler 112A, exceeds 35%, the stiffness of the filler 112A and the strength of the insulating layer 110A as a composite thereof is weakened, which can cause reliability problems. In addition, when the ratio occupied by the concave portion 112a in the total volume of the filler 112 is less than 20%, it may be difficult to set the dielectric constant Dk of the insulating layer 110 to 2.5 or less.

In this case, the resin coated copper in FIG. 3 has only a difference in the shape of the concave portion formed on the filler compared to the resin coated copper in FIG. 1, but features other than these are substantially the same, and thus a detailed description thereof will be omitted.

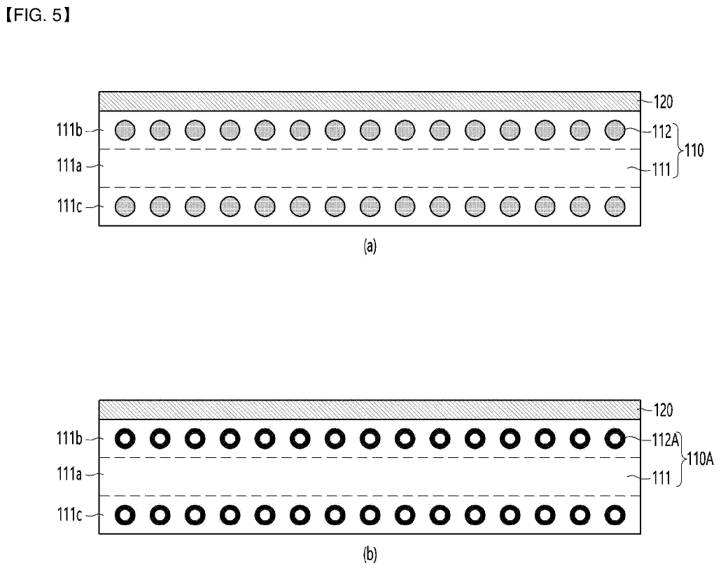

FIG. 5 is a view for explaining an arrangement structure of a filler in a resin coated copper according to an embodiment.

Referring to FIG. 5, a filler may be formed in a specific region of the insulating layer of the resin coated copper in the embodiment

Referring to (a) of FIG. 5, the insulating layer 110 of the resin coated copper may be divided into a plurality of regions in a vertical direction.

For example, the insulating layer 110 may include a first region 111a provided in a center. In addition, the insulating layer 110 may include a second region 111b adjacent to an upper surface of the insulating layer 110 on the first region 111a. In addition, the insulating layer 110 may include a third region 111c adjacent to the lower surface of the insulating layer 110 under the first region 111a.

In addition, the filler 112 may be disposed in a specific region among the first region 111a, the second region 111b, and the third region 111c of the insulating layer 110 in the insulating layer 110. The filler 112 may be a porous filler including the groove shaped concave portion 112a of FIG. 1. That is, in the embodiment, the dielectric constant of the insulating layer 110 is adjusted to 2.5 or less by adjusting the content of the filler 112 in the insulating layer 110 and the porosity of the filler 112. In this case, the content of the filler 112 is limited, and if the filler 112 is dispersed over the entire region within the insulating layer 110, a problem may occur in the reliability of a via hole described later.

Accordingly, in the exemplary embodiment, the filler 112 may be disposed in the second region 111b and the third region 111c except for the first region 111a of the insulating layer 110. In other words, the filler 112 in the embodiment may not be disposed in the first region 111a. For example, the filler 112 in the embodiment may be evenly sprayed and disposed on the second region 111b and the third region 111c. This is to prevent an upper width and a lower width of the via hole from being expanded during a de-smear process performed after the formation of the via hole.

However, the embodiment is not limited thereto, and the filler 112 may be disposed in the first region 111a of the insulating layer 110 as well. In addition, when the filler 112 is also disposed in the first region 111a of the insulating layer 110, a content of the filler disposed in the first region 111a may be smaller than a content of a filler disposed in each of the second region 111b and the third region 111b. Accordingly, in the embodiment, expansion of the via hole can be prevented during the de-smear process of the via hole.

Referring to FIG. 5(b), the insulating layer 110A of the resin coated copper is substantially the same as that of the resin coated copper of FIG. 5(a). However, the fillers 112A including through-hole concave portion may be concentrated in the second region 111b and the third region 111c of the insulating layer 110A in FIG. 5(b).

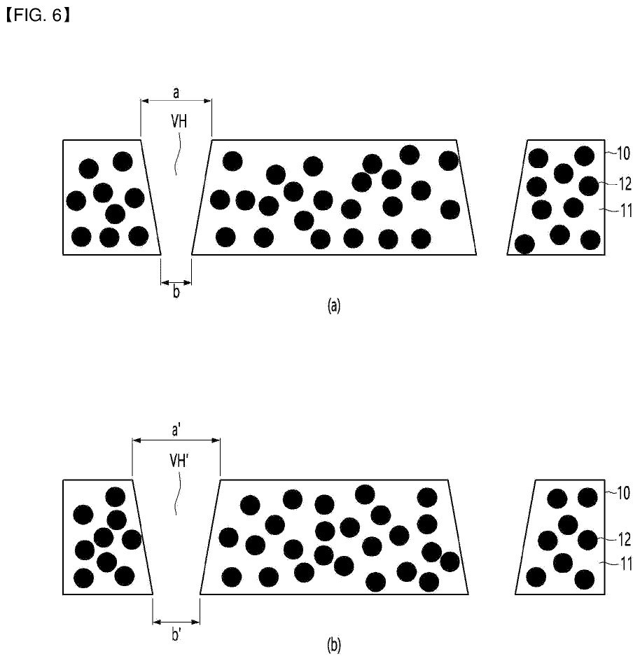

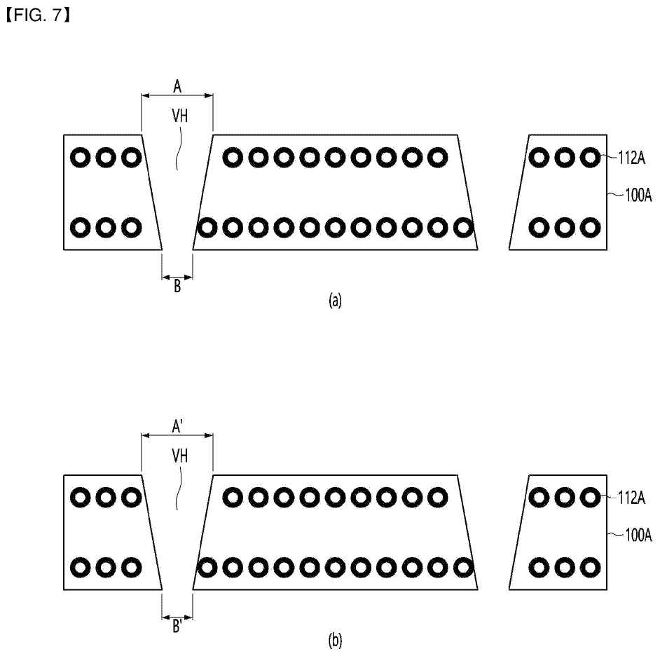

FIG. 6 is a view showing a size change of a via hole according to a comparative example, and FIG. 7 is a view showing a size change of a via hole according to an embodiment.

Referring to (a) of FIG. 6, the insulating layer 10 in the comparative example includes a resin 11 and a filler 12. In this case, in the comparative example, the filler 12 is disposed over an entire region of the insulating layer 10.

In this case, a via hole VH having a first upper width (a) and a first lower width (b) is formed in the insulating layer 10 in the comparative example. In this case, the de-smear process is performed on the inner wall of the via hole (VH) after forming the via hole (VH) in the manufacturing process of a general circuit board.

In this case, when the de-smear process is performed on the insulating layer 10 in the comparative example, a size of the via hole formed in the insulating layer 10 may be increased. Specifically, the via hole (VH′) after the de-smear process has a second upper width (a′) greater than the first upper width (a) and a second lower width (b′) greater than the first lower width (b).

Alternatively, referring to (a) of FIG. 7, the insulating layer in the embodiment may include a resin and a filler. The insulating layer may be the insulating layer of the first embodiment of FIG. 1 or the insulating layer of the second embodiment of FIG. 3. Accordingly, the resin 111 and the fillers 112 and 112A may be disposed in the insulating layer.

In this case, the insulating layer 110 in the embodiment is divided into three regions in the vertical direction, of which the upper second region 111b and the lower third regions (excluding a central first region 111a) 111c) is optionally provided.

Accordingly, in the embodiment, a via hole VH having a third upper width A and a third lower width B may be formed in the insulating layer.

In addition, when the de-smear process is performed on the formed via hole (VH), intensive de-smearing is performed in the first region 111a where the filler is not disposed or the content of the filler is less than that of other regions. Accordingly, the via hole (VH′) after the de-smear process has a fourth upper width (A′) corresponding to the third upper width (A) and a fourth lower width (B′) corresponding to the third lower width (B).

Hereinafter, a resin composition for semiconductors according to a second embodiment will be described. The resin composition for semiconductors in the second embodiment can be applied to a resin coated copper as in the first embodiment.

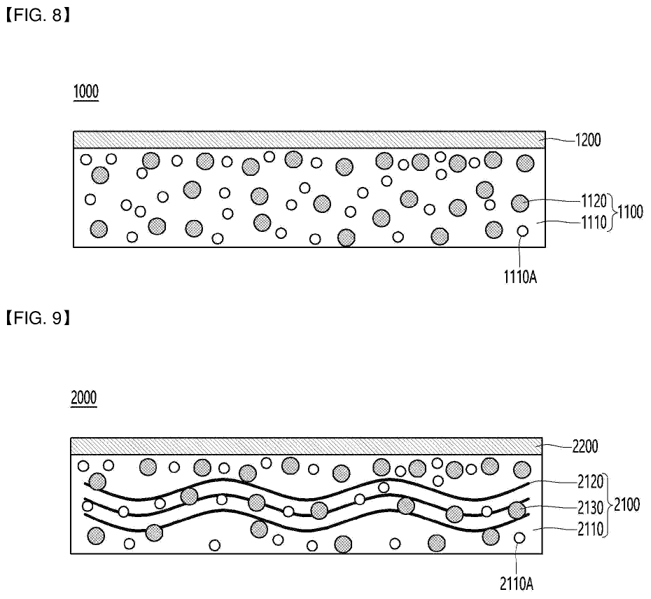

FIG. 8 is a view showing a copper foil-clad resin according to a second embodiment.

The resin coated copper 1000 according to the second embodiment includes an insulating film 1100 (or an insulating layer or a resin composition for a semiconductor package) and a copper foil layer 1200 disposed on one surface of the insulating film 1100.

An insulating layer 1100 includes a resin 1110 and a filler 1120 distributed in the resin 1110.

In the second embodiment, pores can be formed in each of the resin 1110 and the filler 1120 while the filler 1120 has a constant content in the resin 1110 constituting the insulating layer 1100.

Specifically, the insulating layer 1100 includes a resin 1110 having a content in a range of 60 vol. % to 70 vol. % and a filler 1120 having a content in a range of 30 vol. % to 40 vol. %. Here, the insulating layer 1100 of the embodiment is an RCC that does not include glass fibers. Accordingly, in the embodiment, the filler 1120 has a content in a range of 30 vol. % to 40 vol. % so that the insulating layer 1100 can have a certain level or higher strength in the manufacturing process of the circuit board. In addition, in the embodiment, when forming vias (not shown) in the insulating layer 1100, as described above, the filler 1120 having a content in the range of 30 vol. % to 40 vol. % is included in the insulating layer 1100 to ensure quality of the via. That is, in the manufacturing process of the circuit board, a de-smear process is essentially performed after processing a via hole (not shown) using a laser in the insulating layer 1100. In this case, when the content of the filler 1120 is less than 30 vol. %, surface roughness of the via hole may increase, resulting in signal loss. For example, when the content of the filler 1120 is less than 30 vol. %, a problem may occur in the quality of the via. In addition, when the content of the filler 1120 is 40 vol. % or more, it may be difficult to adjust the dielectric constant Dk of the insulating layer 1100 to a low dielectric constant, for example, 2.5 or less. Therefore, in the embodiment, the filler 1120 may have a content of 30 vol. % to 40 vol. % in the insulating layer 1100.

On the other hand, in the first embodiment, there was a limit to lowering the dielectric constant of the insulating layer only by adjusting the contents of the resin and the filler, and accordingly, pores (eg, concave portion) were formed in the filler.

Further, in the second embodiment, in addition to the structure of the first embodiment, pores are formed not only in the filler but also in the resin.

To this end, the resin 1110 in the second embodiment includes the first pore 1110A. A plurality of first pores 1110A may be formed in the resin 1110. That is, the resin 1110 in the embodiment may be a porous resin.

The resin 1110 may have a first porosity. The first porosity may correspond to a ratio of a volume occupied by the first pores 1110A to a total volume of the resin 1110. The first porosity of the resin 1110 may be determined by a second porosity of the filler 1120 to be described later. The first porosity of the resin 1110 will be described in detail below.

In addition, the filler 1120 in the embodiment includes a second pore (not shown). At this time, the second pores may also be referred to as ‘concave portion’ formed on the surface of the filler 1120. Hereinafter, the ‘concave portion’ will be described as a second pore. The second pore may correspond to any one of the concave portions shown in FIGS. 1 and 3. Since the second pores have already been described in FIGS. 1 and 3, a description thereof will be omitted. That is, the second pores may have a groove shape of a non-penetrating structure as shown in FIG. 1, or may have a through hole shape of a penetrating structure as shown in FIG. 3.

Meanwhile, the first porosity of the resin 1110 may have an inversely proportional relationship with the second porosity of the filler 1120. For example, the second porosity of the filler 1120 may decrease as the first porosity of the resin 1110 increases. Conversely, the second porosity of the filler 1120 may increase as the first porosity of the resin 1110 decreases.

On the other hand, the dielectric constant of the insulating layer 1100 may be determined by the dielectric constant of the resin 1110, the dielectric constant of the filler 1120, the content of the resin 1110, the content of the filler 1120, the dielectric constant of the resin 1110, the first porosity of the resin 1110, and the second porosity of the filler 1120. Meanwhile, the first porosity and the second porosity may also be referred to as a first porosity rate and a second porosity rate, and may be expressed as “porosity, %”.

In this case, the resin 1110 of the insulating layer 1100 in the second embodiment is formed of a modified epoxy or maleimide series, as in the first embodiment, and the filler 1120 may include a ceramic material of any one SiO₂, ZrO₃, HfO₂, and TiO₂.

On the other hand, when a content of the filler 1120 is less than 30 vol. % in the insulating layer 1100, the stiffness of the insulating layer 1100 is weakened, resulting in reliability problems during the manufacturing process of the circuit board. For example, when a content of the filler 1120 is less than 30 vol. % in the insulating layer 1100, the degree of warping of the insulating layer 1100 becomes severe during the manufacturing process of the circuit board, and accordingly, a problem in which a normal manufacturing process cannot proceed may occur. In addition, when the content of the filler 1120 in the insulating layer 1100 is less than 30 vol. %, the signal loss amount of vias formed in the insulating layer 1100 may increase, reliability problems may occur accordingly. Accordingly, the embodiment allows the filler 1120 to have a content of 30 vol. % or more in the insulating layer 1100.

In addition, when a content of the filler 1120 exceeds 40 vol. % in the insulating layer 1100, it may be difficult to match the dielectric constant (Dk) of the insulating layer 1100 to 2.5 or less. For example, when a content of the filler 1120 exceeds 40 vol. % in the insulating layer 1100, the first porosity of the resin 1110 or the second porosity of the filler 1120 must be increased in the total volume of the filler 1120 in order to adjust the dielectric constant (Dk) of the insulating layer 1100 to 2.5 or less, and accordingly, the stiffness of the resin 1110 or the filler 1120 may be weakened, resulting in a reliability problem.

Therefore, the content of the filler 1120 has a range of 30 vol. % to 40 vol. % in the insulating layer 1100. Correspondingly, a content of the resin 1110 has a range of 60 vol. % to 70 vol. % in the insulating layer 1100.

Meanwhile, the first porosity of the resin 1110 and the second porosity of the filler 1120 may be as follows.

The first porosity of the resin 1110 in the embodiment may have a range of 10% to 35%.

When the first porosity of the resin 1110 is less than 10%, it may be difficult to set the dielectric constant of the insulating layer 1100 to 2.5 or less. In addition, when the first porosity of the resin 1110 exceeds 35%, reliability problems may occur in the stiffness of the resin 1110 and the insulating layer 1100 including the resin 1110 due to the increase in the first pores 1110A.

In this case, the first porosity of the resin 1110 may be adjusted within the range of 10% to 35% based on the second porosity of the filler 1120.

The second porosity of the filler 1120 may have a range of 10% to 35%.

When the second porosity of the filler 1120 is less than 10%, it may be difficult to adjust the dielectric constant of the insulating layer 1100 to 2.5 or less. In addition, when the second porosity of the filler 1120 exceeds 35%, a problem may occur in the stiffness of the filler 1120 due to the increase in the second porosity. For example, when the second porosity of the filler 1120 exceeds 35%, a reliability problem such as cracking of the filler 1120 may occur in the insulating layer 1100. Therefore, in the embodiment, the second porosity of the filler 1120 can be adjusted within a range of 10% to 35%. Meanwhile, the second porosity of the filler 1120 may be adjusted based on the porosity of the resin 1110.

The dielectric constant of the insulating layer 1100 according to the first porosity of the resin 1110 and the second porosity of the filler 1120 may be as shown in Table 4 below.

TABLE 4

| Second | | | | | | | | |
|---|---|---|---|---|---|---|---|---|
| porosity of | | | | | | | | |
| filler having | | First porosity of the resin having the first | | | | | | |
| second pores | | porosity (porosity, %) | | | | | | |
| (porosity, %) | | | 0 | 0 | 5 | 0 | 5 | 40 |
| 0 | dielectric | .6 | .56 | .55 | .52 | .50 | .47 | 2.44 |
| | constant | | | | | | | |
| 0 | dielectric | .58 | .55 | .53 | .50 | .48 | .45 | 2.42 |
| | constant | | | | | | | |
| 0 | dielectric | .52 | .49 | .47 | .44 | .42 | .39 | 2.35 |
| | constant | | | | | | | |
| 5 | dielectric | .51 | .47 | .45 | .43 | .40 | .38 | 2.33 |
| | constant | | | | | | | |
| 0 | dielectric | .49 | .46 | .44 | .41 | .39 | .36 | 2.31 |
| | constant | | | | | | | |

In the embodiment, the dielectric constant (Dk) of the insulating layer 1100 can be adjusted to 2.5 or less. Accordingly, the dielectric constant according to the first porosity of the resin 1110 including the first pores 1110A and the second porosity of the filler 1120 having the recess-shaped second pores is shown in Table 3. In this case, as described above, the first porosity of the resin 1110 is adjusted within a range of 10% to 35%. In addition, the second porosity of the filler 1120 is adjusted within a range of 10% to 35%.

Hereinafter, a second porosity that the filler 1120 should have will be described based on the first porosity of the resin 1110.

That is, in the embodiment, the first porosity of the resin 1110 is determined within the range of 10% to 35%, and the second porosity of the filler 1120 can be adjusted based on the first porosity of the resin. Conversely, in the embodiment, the second porosity of the filler 1120 is determined within the range of 10% to 35%, and the first porosity of the resin 1110 can be adjusted based on the second porosity of the filler.

(1) The Second Porosity of the Filler 1120 According to the First Porosity of the Resin

As described above, the first porosity of the resin 1110 may be determined within a range of 10% to 35%.

For example, the first porosity of the resin 1110 may be determined to be 10% to 20%. In this case, the second porosity of the filler 1120 is adjusted within a range of 30% to 35%.

In addition, the first porosity of the resin 1110 may be determined to be 21% to 25%. In this case, the second porosity of the filler 1120 is adjusted within a range of 20% to 35%.

In addition, the first porosity of the resin 1110 may be determined to be 26% to 30%. In this case, the second porosity of the filler 1120 is adjusted within a range of 15% to 35%.

In addition, the first porosity of the resin 1110 may be determined to be 31% to 35%. In this case, the second porosity of the filler 1120 is adjusted within a range of 10% to 35%.

(2) The First Porosity of the Resin 1110 According to the Second Porosity of the Filler 1120

Conversely, in the embodiment, the second porosity of the filler 1120 is determined within a specific range, and, the first porosity of the resin 1110 may be adjusted so that the dielectric constant Dk of the insulating layer 1100 is 2.5 or less based on the second porosity of the filler.

For example, the second porosity of the filler 1120 may be determined to be 10% to 20%. In this case, the first porosity of the resin 1110 may be adjusted within a range of 30% to 35%.

For example, the second porosity of the filler 1120 may be determined to be 21% to 35%. In this case, the first porosity of the resin 1110 may be adjusted within a range of 10% to 35%.

As described above, the embodiment allows the dielectric constant Dk of the insulating layer 1100, which is a composite of the resin 1110 and the filler 1120, to have 2.5 or less by adjusting the dielectric constant of resin 1110, the dielectric constant of the filler 1120, the content of the resin 1110, the content of the filler 1120, the first porosity of the resin 1110, and the second porosity of the filler 1120.

Meanwhile, the dielectric constant of the insulating layer 1110 may be measured through the following equipment and methods. That is, the insulating layer 1110 is not used as a single product, but can be used as a resin coated copper in which a copper foil layer 120 is laminated on at least one surface thereof. In this case, the dielectric constant of the insulating layer 1100 may be measured by proceeding with a process of removing the copper foil layer 120 from the resin coated copper, a process of drying the insulating layer 110 at 100° C. for 60 minutes in a state where the copper foil layer 120 is removed, and a process of measuring this using a resonator using an N5222A PNA Network analyzer (Agilent) device under conditions of 25° C. and 50% RH by a split post dielectric resonance (SPDR) method.

According to this, in the embodiment, the dielectric constant (Dk) of the insulating layer 1100 can be adjusted to 2.5 or less while maintaining the rigidity of the insulating layer 1100, thereby providing a circuit board suitable for high-frequency signal transmission. In addition, in the embodiment, the second pores is provided in the filler 1120, and the degree of thermal expansion generated when the temperature of the filler 1120 is changed can be reduced by the second pores. A thermal strain of the insulating layer, which is a composite of the filler and the insulating layer, can be improved.

Meanwhile, as shown in FIG. 5, the fillers included in the insulating layer in the second embodiment may be concentrated in the second region adjacent to the upper surface and the third region adjacent to the lower surface of the insulating layer.

Hereinafter, a resin composition for semiconductors according to a third embodiment will be described. Unlike the first and second embodiments, the resin composition for semiconductors in the third embodiment may be applied to the copper clad laminate.

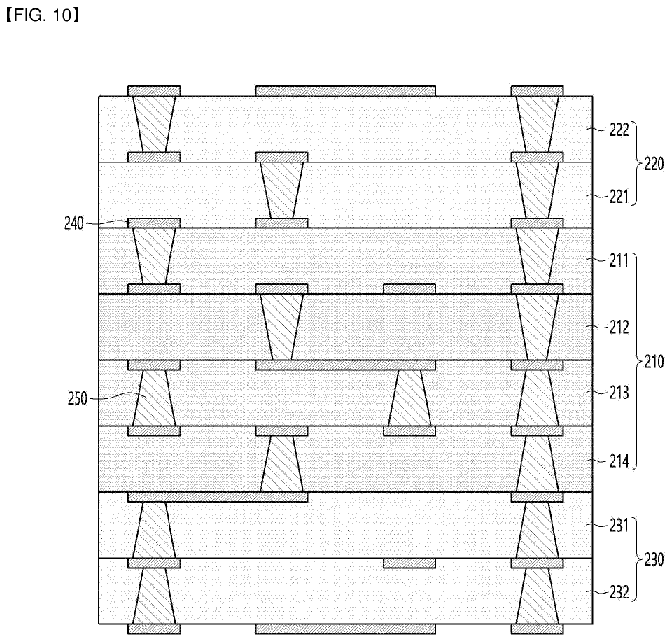

FIG. 9 is a view showing a copper clad laminate including a resin composition for a semiconductor package according to a third embodiment.

A copper clad laminate according to the third embodiment includes an insulating film (2100, or insulating layer or resin composition for semiconductor package) and a copper foil layer 2200 disposed on one surface of the insulating film 2100. The insulating film 2100 may also be referred to as an insulating layer. The insulating film 2100 may be prepreg (PPG). Hereinafter, the insulating film corresponding to the prepreg will be referred to as the insulating layer 2100 for convenience of description.

The insulating layer 2100 includes a resin 2110, a glass fiber 2120, and a filler 2130. That is, the insulating layer 2100 may include the glass fiber 2120 and the filler 2130 dispersed in the resin 2110. That is, the insulating layer 2100 in the embodiment may be a prepreg in which a certain amount of the glass fiber 2120 and the filler 2130 are dispersed in the resin 2110. For example, the insulating layer 2100 in the embodiment may be a prepreg that is a composite of the resin 2110, the glass fiber 2120, and the filler 2130.

The insulating layer 2100 may be a resin for a semiconductor package. In an embodiment, the dielectric constant (Dk) of the insulating layer 2100 can be adjusted to 2.5 or less through a change in the composition of the insulating layer 2100 constituting the resin for the semiconductor package. Hereinafter, the resin for the semiconductor package is referred to as the insulating layer 2100, and a resin composition for the semiconductor package corresponding to the insulating layer 2100 will be described in detail.

Such an insulating layer 2100 is a composite of the resin 2110, the glass fiber 2120, and the filler 2130.

In this case, in the third embodiment, unlike the first and second embodiments, the insulating layer 2100 has a structure in which the glass fiber 2120 are included, and through this, the insulating layer 2100 can have a dielectric constant Dk of 2.5 or less by forming pores in the resin 2110 and the filler 2130 constituting the insulating layer 2100 while allowing the insulating layer 2100 to have a certain level or higher strength.

That is, the embodiment allows pores to be formed in each of the resin 2110 and the filler 2130 while the glass fibers 2120 and the filler 2130 have a certain content in the resin 2110 constituting the insulating layer 2100.

Specifically, the filler 2130 may occupy a range of 20 vol. % to 30 vol. % with respect to a total volume of the insulating layer 2100. Here, when the content of the filler 2130 exceeds 30 vol. %, it may be difficult to adjust the dielectric constant of the insulating layer 2100 to a low dielectric constant, for example, 2.5 or less. In addition, when the content of the filler 2130 is less than 20 vol. %, the insulating layer 2100 cannot have strength greater than a certain level. Accordingly, in the embodiment, the content of the filler 2130 may have a range of 20 vol. % to 30 vol. % in the insulating layer 2100.

In addition, the glass fiber 2120 occupies 50 vol. % to 70 vol. % of the total volume of the insulating layer 2100. When the glass fiber 2120 exceeds 70 vol. %, it may be difficult to match the dielectric constant Dk of the insulating layer 2100 to a low dielectric constant, for example, 2.5 or less. In addition, when the content of the glass fibers 2120 is less than 50 vol. %, the insulating layer 2100 cannot have strength greater than a certain level. Accordingly, in the embodiment, the glass fibers 2120 may have 50 vol. % to 70 vol. % in the insulating layer 2100.

In this case, the resin 2110 in the third embodiment includes the first pore 2110A. A plurality of first pores 2110A may be formed in the resin 2110. That is, the resin 2110 in the embodiment may be a porous resin.

The resin 2110 may have a first porosity. The first porosity may correspond to a ratio of a volume occupied by the first pores 2110A to a total volume of the resin 2110. The first porosity of the resin 2110 may be determined by the second porosity of the filler 2130 to be described later. The first porosity of the resin 2110 will be described in detail below.

In addition, the filler 2130 in the embodiment includes a second pore (not shown). In this case, the second pores may also be referred to as ‘concave portion’ formed on the surface of the filler 2130. Hereinafter, the ‘concave portion’ will be described as a second pore.

The structure of the first pore 2110A and the second pore is substantially the same as that of the first pore and the second pore of the second embodiment shown in FIG. 8, and a detailed description thereof will be omitted.

On the other hand, when the content of the filler 2130 is less than 20 vol. % in the insulating layer 2100, the rigidity of the insulating layer 2100 is weakened, and thus a reliability problem may occur during a manufacturing process of a circuit board. For example, when the content of the filler 2130 is less than 20 vol. % in the insulating layer 2100, the degree of warping of the insulating layer 2100 becomes severe during the manufacturing process of the circuit board, and thus, a problem in which a normal manufacturing process cannot proceed may occur. In addition, when the content of the filler 2130 exceeds 30 vol. % in the insulating layer 2100, it may be difficult to adjust the dielectric constant Dk of the insulating layer 2100 to 2.5 or less. For example, when the content of the filler 2130 exceeds 30 vol. % in the insulating layer 2100, the first porosity of the resin 2110 or the second porosity of the filler 2130 in the total volume of the filler 2130, should be increased in order to adjust the dielectric constant (Dk) of the insulating layer 2100 to 2.5 or less, accordingly, the stiffness of the resin 2110 or the filler 2130 may be weakened, resulting in a reliability problem.

Therefore, the content of the filler 2130 in the insulating layer 2100 has a range of 20 vol. % to 30 vol. %. In addition, the content of the glass fiber 2120 in the insulating layer 2100 has a range of 50 vol. % to 70 vol. %.

Meanwhile, the second pore may be formed only in the filler 2130 in a state in which the first pore 2110A are not formed in the resin 2110, thereby allowing the insulating layer 2100 to have a certain level of dielectric constant. However, in this case, it may be difficult to make the insulating layer 2100 have a dielectric constant Dk of 2.5 or less only with the second porosity of the filler 2130.

That is, the dielectric constant of the insulating layer 2100 may be as shown in Table 5 below only with the second porosity of the filler 2130 without the first pores 2110A being formed in the resin 2110.

TABLE 5

| | | Filler porosity(%) | | | | | |
|---|---|---|---|---|---|---|---|
| | | [symbol] % | [symbol] 0% | [symbol] 0% | [symbol] 5% | [symbol] 0% | [symbol] 5% |
| Glass fiber | k | [symbol] .1 | [symbol] .99 | [symbol] .88 | [symbol] .77 | [symbol] .66 | [symbol] .55 |
| (Dk = 3.7~4.1) | | | | | | | |
| resin | | | | | | | |
| (Dk = 2.4) | | | | | | | |

[symbol]

indicates data missing or illegible when filed

As in Table 5 above, when the second porosity of the second pores provided in the filler 2130 is adjusted in a state in which the glass fibers 2120 are impregnated in the resin 2110, the dielectric constant Dk of the insulating layer 2100 cannot be adjusted to 2.5. specifically, the second porosity of the filler 2130 should be 40% to 50% or more in order to adjust the dielectric constant (Dk) of the insulating layer 2100 to 2.5 or less in a state in which the glass fibers 2120 are included in the resin 2110. However, when the second porosity of the filler 2130 exceeds 35%, the strength of the filler 2130 is weakened, and reliability problems such as breakage of the filler 2130 may occur in various environments. Accordingly, the embodiment further forms first pores 2110A in the resin 2110 while allowing the filler 2130 to have second pores, and accordingly, the dielectric constant Dk of the insulating layer 2100 is set to 2.5 or less by a combination of the first porosity of the resin 2110 and the second porosity of the filler 2130. Meanwhile, the first porosity of the resin 2110 and the second porosity of the filler 2130 may be as follows.

In an embodiment, the first porosity of the resin 2110 may have a range of 10% to 35%.

When the first porosity of the resin 2110 is less than 10%, it may be difficult to set the dielectric constant Dk of the insulating layer 2100 to 2.5 or less. In addition, when the first porosity of the resin 2110 exceeds 35%, a reliability problem may occur in the rigidity of the resin 2110 and the insulating layer 2100 including the resin 2110 due to the increase in the first pores 2110A.

In this case, the first porosity of the resin 2110 may be adjusted within the range of 10% to 35% based on the second porosity of the filler 2130.

The second porosity of the filler 2130 may a range of 10% to 35%.

When the second porosity of the filler 2130 is less than 10%, it may be difficult to set the dielectric constant Dk of the insulating layer 2100 to 2.5 or less. In addition, when the second porosity of the filler 2130 exceeds 35%, a problem may occur in the stiffness of the filler 2130 due to the increase in the second porosity. For example, when the second porosity of the filler 2130 exceeds 35%, a reliability problem such as cracking of the filler 2130 may occur in the insulating layer 2100. Therefore, in the embodiment, the second porosity of the filler 2130 can be adjusted within a range of 10% to 35%. Meanwhile, the second porosity of the filler 2130 may be adjusted based on the porosity of the resin 2110.

Since the dielectric constant of the insulating layer 2100 according to the first porosity of the resin 2110 and the second porosity of the filler 2130 has already been described in Table 4, a detailed description thereof will be omitted.

As described above, the embodiment allows the dielectric constant Dk of the insulating layer 2100, which is a composite of the resin 2110, the glass fiber 2120 and the filler 2130, to have 2.5 or less by adjusting the dielectric constant of resin 2110, the dielectric constant of the glass fiber 2120, the dielectric constant of the filler 2130, the content of the resin 2110, the content of the glass fiber 2120, the content of the filler 2130, the first porosity of the resin 2110, and the second porosity of the filler 2130.

Meanwhile, the dielectric constant of the insulating layer 2110 may be measured through the following equipment and methods. That is, the insulating layer 2110 is not used as a single product, but can be used as a copper clad laminate in which a copper foil layer 120 is laminated on at least one surface thereof. Meanwhile, the dielectric constant of the insulating layer 2100 may be measured by proceeding with a process of removing the copper foil layer 120 from the copper clad laminate resin coated copper, a process of drying the insulating layer 110 at 100° C. for 60 minutes in a state where the copper foil layer 120 is removed, and a process of measuring this using a resonator using an N5222A PNA Network analyzer (Agilent) device under conditions of 25° C. and 50% RH by a split post dielectric resonance (SPDR) method.

According to this, in the embodiment, the dielectric constant (Dk) of the insulating layer 2100 can be adjusted to 2.5 or less while maintaining the rigidity of the insulating layer 2100, thereby providing a circuit board suitable for high-frequency signal transmission. In addition, in the embodiment, the second pores is provided in the filler 2130, and the degree of thermal expansion generated when the temperature of the filler 2130 is changed can be reduced by the second pores. A thermal strain of the insulating layer, which is a composite of the filler and the insulating layer, can be improved.

Hereinafter, a circuit board formed using the resin coated copper shown in any one of FIGS. 1, 3 and 8 will be described.

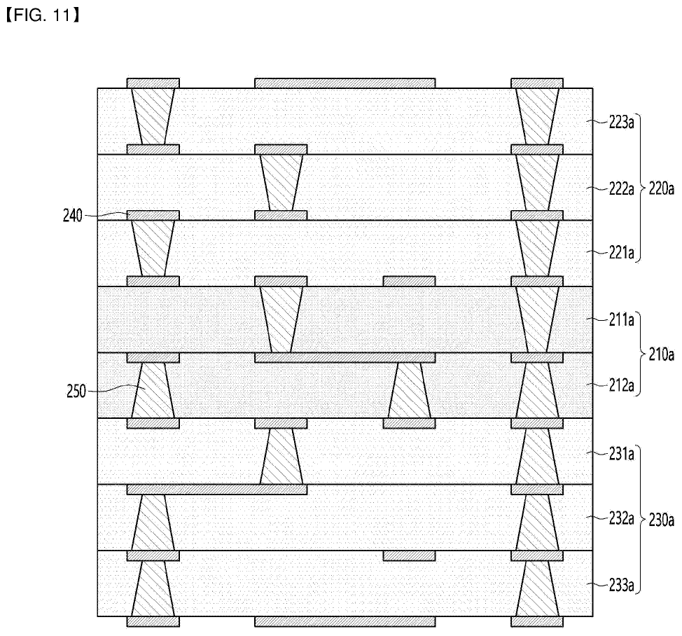

FIG. 10 is a view showing a circuit board according to the first embodiment.

Referring to FIG. 10, the circuit board may include an insulating board including first to third insulating portions 210, 220, and 230, a circuit pattern 240, and a via 250.

The insulating substrate including the first to third insulating portions 210, 220 and 230 may have a flat plate structure. The insulating substrate may be a printed circuit board (PCB). Here, the insulating substrate may be implemented as a single substrate, or alternatively, may be implemented as a multilayer substrate in which a plurality of insulating layers are successively laminated.

Accordingly, the insulating substrate may include a plurality of insulating portions 210, 220, and 230. The plurality of insulating portions includes a first insulating portion 210, a second insulating portion 220 disposed on the first insulating portion 210, and a third insulating portion 230 disposed under the first insulating portion 210.

In this case, the first insulating portion 210, the second insulating portion 220, and the third insulating portion 230 may be composed of different insulating materials. Preferably, the first insulating portion 210 may include glass fibers. In addition, the second insulating portion 220 and the third insulating portion 230 may not include the glass fiber unlike the first insulating portion 210. Preferably, the second insulating portion 220 and the third insulating portion 230 may include the resin coated copper shown in any one of FIGS. 1 and 3.

Accordingly, a thickness of each insulating layer constituting the first insulating portion 210 may be different from a thickness of each insulating layer constituting the second insulating portion 220 and the third insulating portion 230. In other words, the thickness of each insulating layer constituting the first insulating portion 210 may be greater than the thickness of each insulating layer constituting the second insulating portion 220 and the third insulating portion 230.

That is, the first insulating portion 210 includes glass fibers. The glass fiber generally has a thickness of about 12 μm. Accordingly, the thickness of each insulating layer constituting the first insulating portion 210 includes the thickness of the glass fiber and may have a range of 19 μm to 23 μm. In this case, the first insulating portion 210 may include the composition for a semiconductor package shown in FIG. 9. For example, the first insulating portion 210 may be composed of the copper-clad laminate shown in FIG. 9.

Unlike this, the second insulating portion 220 does not include the glass fiber. Preferably, each insulating layer constituting the second insulating portion 220 may be made of a resin coated copper (RCC). Specifically, the second insulating portion 220 may be made of the resin coated copper shown in any one of FIGS. 1, 3, and 8.

Accordingly, the thickness of each insulating layer constituting the second insulating portion 220 may have a range of 10 μm to 15 μm. Preferably, the thickness of each layer of the second insulating portion 220 made of the resin coated copper may be formed within a range not exceeding 15 μm.

In addition, the glass fiber is not included in the third insulating portion 230. Preferably, each insulating layer constituting the third insulating portion 230 may be made of a resin coated copper (RCC). Specifically, the third insulator 230 may be made of the resin coated copper shown in any one of FIGS. 1, 3, and 8. Accordingly, the thickness of each insulating layer constituting the third insulating portion 230 may range from 10 μm to 15 μm.

That is, the insulating portion constituting the circuit board in the comparative example includes a plurality of insulating layers, and all of the plurality of insulating layers are made of prepreg (PPG) containing glass fibers. In this case, it is difficult to reduce the thickness of the glass fiber in the circuit board in the comparative example based on PPG. This is because, when the thickness of the PPG is reduced, glass fibers included in the PPG can be electrically connected to circuit patterns disposed on the surface of the PPG, resulting in a crack risk. Accordingly, when the thickness of the PPG of the circuit board in the comparative example is reduced, dielectric breakdown and damage to the circuit pattern may occur accordingly. Accordingly, the circuit board in the comparative example had a limitation in reducing the overall thickness due to the thickness of the glass fibers constituting the PPG.

In addition, the printed circuit board in the comparative example has a high dielectric constant because it is composed of an insulating layer made of only PPG containing glass fibers. However, when the dielectric has a high dielectric constant, there is a problem in that it is difficult to approach as a high frequency substitute. That is, since the dielectric constant of the glass fiber is high in the circuit board of the comparative example, a phenomenon in which the dielectric constant is destroyed occurs in a high frequency band.

Accordingly, in the embodiment, the insulating layer is formed using the resin coated copper having a low dielectric constant, thereby reducing the thickness of the circuit board and providing a highly reliable circuit board in which signal loss is minimized even in a high frequency band. This can be achieved by the dielectric constant of each insulating layer constituting the second insulating portion 220 and the third insulating portion 230.

The first insulating portion 210 may include a first insulating layer 211, a second insulating layer 212, a third insulating layer 213, and a fourth insulating layer 214 from a lower portion. Also, each of the first insulating layer 211, the second insulating layer 212, the third insulating layer 213, and the fourth insulating layer 214 may be made of PPG containing glass fibers.

On the other hand, in the embodiment of the present application, the insulating substrate may be composed of 8 layers based on the insulating layer. However, the embodiment is not limited thereto and a total number of layers of the insulating layer may be increased or decreased.

Also, in the first embodiment, the first insulating portion 210 may be composed of four layers. For example, in the first embodiment, the first insulating portion 210 may be composed of four layers of prepreg.

In addition, the second insulating portion 220 may include a fifth insulating layer 221 and a sixth insulating layer 222 from a lower portion. The fifth insulating layer 221 and the sixth insulating layer 222 constituting the second insulating portion 220 may be made of the resin coated copper having a low dielectric constant and a low coefficient of thermal expansion. That is, in the first embodiment, the second insulating portion 220 may be composed of two layers. For example, in the first embodiment, the second insulating portion 220 may be composed of two layers of the resin coated copper.

In addition, the third insulating portion 230 may include a seventh insulating layer 231 and an eighth insulating layer 232 from an upper portion. The seventh insulating layer 231 and the eighth insulating layer 232 constituting the third insulating portion 230 may be made of the resin coated copper having a low dielectric constant and a low coefficient of thermal expansion. That is, in the first embodiment, the third insulating portion 230 may be composed of two layers. For example, in the first embodiment, the third insulating portion 230 may be composed of two layers of the resin coated copper.

Meanwhile, in the first embodiment, it has been described that the total number of layers of the insulating layer is eight, the first insulating portion 210 formed of prepreg is formed in four layers among the insulating layer, and each of the second insulating portion 220 and the third insulating portion 230 formed of the resin coated copper has two layers, but it is not limited thereto, and the number of insulating layers constituting the first insulating portion 210 may increase or decrease.

Meanwhile, a circuit pattern 240 may be disposed on a surface of an insulating layer constituting each of the first insulating portion 210, the second insulating portion 220, and the third insulating portion 230.

Preferably, the circuit pattern 240 may be disposed on at least one surface of each of the first insulating layer 211, the second insulating layer 212, the third insulating layer 213, the fourth insulating layer 214, the fifth insulating layer 221, the sixth insulating layer 222, the seventh insulating layer 231 and the eighth insulating layer 232.

The circuit pattern 240 is a wiring that transmits an electrical signal, and may be formed of a metal material having high electrical conductivity. To this end, the circuit pattern 240 may be formed of at least one metal material selected from gold (Au), silver (Ag), platinum (Pt), titanium (Ti), tin (Sn), copper (Cu), and zinc (Zn).

In addition, the circuit pattern 240 may be formed of a paste or solder paste including at least one metal material selected from gold (Au), silver (Ag), platinum (Pt), titanium (Ti), tin (Sn), copper (Cu), and zinc (Zn) having excellent bonding power. Preferably, the circuit pattern 240 may be formed of copper (Cu) having high electrical conductivity and a relatively inexpensive price.

In addition, the circuit pattern 240 may have a thickness of 12 μm±2 μm. That is, the thickness of the circuit pattern 240 may range from 10 μm to 14 μm.

The circuit pattern 240 may be formed by an additive process, a subtractive process, a modified semi additive process (MSAP), and a semi additive process (SAP) process, which are typical circuit board manufacturing processes. and a detailed description thereof will be omitted here.

At least one via 250 is formed in at least one of the plurality of insulating layers constituting the first insulating portion 210, the second insulating portion 220, and the third insulating portion 230. The via 250 is disposed penetrating at least one insulating layer among the plurality of insulating layers. The via 250 may pass through only one insulating layer among the plurality of insulating layers, or may be formed to pass through at least two insulating layers in common. Accordingly, the vias 250 electrically connect circuit patterns disposed on surfaces of different insulating layers to each other.

The via 250 may be formed by filling an inside of a via hole (not shown) formed in each insulating layer with a conductive material.

The via hole may be formed by any one of mechanical, laser, and chemical processing. When the through hole is formed by machining, methods such as milling, drilling, and routing may be used, and when formed by laser processing, a UV or CO2 laser method may be used. In addition, when formed by chemical processing, a chemical containing aminosilane, ketones, or the like may be used. Accordingly, at least one of plurality of insulating layers may be opened.

Meanwhile, the laser processing is a cutting method that concentrates optical energy on a surface to melt and evaporate a part of the material to take a desired shape, accordingly, complex formations by computer programs can be easily processed, and even composite materials that are difficult to cut by other methods can be processed.

In addition, the laser processing has a cutting diameter of at least 0.005 mm, and has a wide range of possible thicknesses.

As the laser processing drill, it is preferable to use a YAG (Yttrium Aluminum Garnet) laser, a CO2 laser, or an ultraviolet (UV) laser. YAG laser is a laser that can process both copper foil layers and insulating layers, and CO2 laser is a laser that can process only insulating layers.

When the through hole is formed, the via 250 may be formed by filling the inside of the through hole with a conductive material. The metal material forming the via 250 may be any one material selected from copper (Cu), silver (Ag), tin (Sn), gold (Au), nickel (Ni), and palladium (Pd). In addition, the conductive material filling may use any one or a combination of electroless plating, electrolytic plating, screen printing, sputtering, evaporation, inkjetting and dispensing.

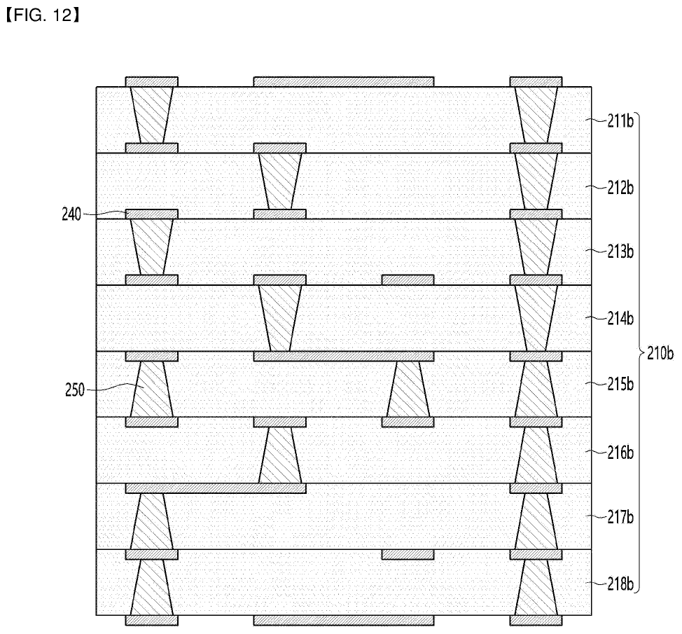

FIG. 11 is a view showing a circuit board according to a second embodiment, and FIG. 12 is a view showing a circuit board according to a third embodiment.

Referring to FIGS. 11 and 12, the circuit board has a difference in the number of layers of the first insulating portion composed of PPG and the number of layers of the second insulating portion and the third insulating portion composed of the resin coated copper in the entire laminated structure of the insulating board.

Referring to FIG. 11, the circuit board in the second embodiment includes a first insulating portion 210a, a second insulating p part 220a, and a third insulating p part 230a.

Also, the first insulating portion 210a may include two layers of PPGs 211a and 212a. The PPGs 211a and 212a may be a general PPG according to a prior art, or may be a prepreg of the copper clad laminate of FIG. 9 including the resin composition for a semiconductor package according to the third embodiment of the present application.

In addition, the second insulating portion 220a may include three-layer RCCs 221a, 222a, and 223a shown in any one of FIGS. 1, 3, and 8.

In addition, the third insulating portion 230a may include three-layer RCCs 231a, 232a, and 233a shown in any one of FIGS. 1, 3, and 8.

Referring to FIG. 12, the circuit board in the third embodiment may include only one insulating portion 210b.

Also, the insulating portion 210b may have an 8-layer structure.

In addition, the insulating portion 210b may include RCCs 211b, 212b, 213b, 214b, 215b, 216b, 217b, and 218b shown in any one of FIGS. 1, 3, and 8.

The embodiment provides a resin composition for a semiconductor package constituting an insulating layer or an insulating film, which is a composite of resin and filler. In this case, the filler of the embodiment includes at least one concave portion provided on a surface. In addition, the embodiment controls a dielectric constant of the resin, a dielectric constant of the filler, a content of the resin, a content of the filler, and a ratio (eg, porosity) occupied by the concave portion in the filler. Accordingly, the embodiment may adjust the dielectric constant of the insulating layer or the insulating film to 2.5 Dk or less while maintaining a rigidity of the insulating layer or the insulating film, and accordingly, it is possible to provide a circuit board suitable for high-frequency signal transmission.

In addition, the embodiment includes a concave portion in the filler, a degree of thermal expansion generated when the temperature of the filler is changed can be reduced by the concave portion, and thus the thermal strain of the insulating layer, which is a composite of the filler and the resin, can be improved.

Meanwhile, the insulating layer or the insulating film in the embodiment may include a first region provided in a center, a second region provided on the first region, and a third region provided under the first region. In this case, the filler of the embodiment may be selectively disposed in the second region and the third region except for the first region. Alternatively, the filler of the embodiment may be disposed in the first to third regions. In this case, a content of the filler in the first region is smaller than a content of the filler in each of the second region and the third region. Accordingly, the embodiment can prevent an unintentional size expansion of the via hole in a process of de-smearing after forming a via hole in the insulating layer or insulating film, and accordingly, it is possible to form a fine via.

Accordingly, the embodiment can provide a highly reliable circuit board in which signal loss is minimized even in a high frequency band while the thickness of the circuit board is slimmed down by providing the insulating layer using a resin coated copper having a low dielectric constant.

The characteristics, structures and effects described in the embodiments above are included in at least one embodiment but are not limited to one embodiment. Furthermore, the characteristics, structures, effects, and the like illustrated in each of the embodiments may be combined or modified even with respect to other embodiments by those of ordinary skill in the art to which the embodiments pertain. Thus, it would be construed that contents related to such a combination and such a modification are included in the scope of the embodiments.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the present invention defined in the appended claims.

1. A resin composition for a semiconductor package, comprising:
a resin composition that is a composite of a resin and a filler disposed in the resin,
wherein the resin is divided into a plurality of regions along a thickness direction between an upper surface of the resin and a lower surface of the resin, and
wherein the filler is provided with different contents in the plurality of regions.

2-10. (canceled)

11. The resin composition of claim 1, wherein a content of the filler in a region adjacent to the upper or lower surface of the resin is greater than a content of the filler in an inner region of the resin spaced apart from the upper or lower surface of the resin.

12. The resin composition of claim 1, wherein the filler includes at least one concave portion provided on a surface,
wherein a content of the filler has a range of 10 vol. % to 40 vol % of a total volume of the resin composition, and
wherein a porosity corresponds to a volume occupied by the concave portion in a total volume of the filler and has a range of 20% to 35%.

13. The resin composition of claim 1, wherein a dielectric constant (Dk) of the resin composition including the resin and the filler is 2.5 or less.

14. The resin composition of claim 1, wherein the concave portion includes a recess not penetrating the filler or a through hole passing through the filler.

15. The resin composition of claim 1, wherein the resin is formed of a modified epoxy or maleimide series, and
wherein the resin has a dielectric constant in a range of 2.3 to 2.5.

16. The resin composition of claim 1, wherein the filler includes a ceramic material of any one of SiO₂, ZrO₃, HfO₂, and TiO₂, and has a dielectric constant in a range of 3.7 to 4.2.

17. The resin composition of claim 12, wherein the filler has a content in a range of 10 vol. % to 15 vol %, and
wherein the porosity has a range of 20% to 35%.

18. The resin composition of claim 12, wherein the filler has a content in a range of 15 vol. % to 30 vol %, and
wherein the porosity has a range of 30% to 35%.

19. The resin composition of claim 12, wherein the filler has a content in a range of 30 vol. % to 40 vol %, and
wherein the porosity has a range of 32% to 35%.

20. The resin composition of claim 1, wherein the plurality of regions includes:
a first region adjacent to the upper surface of the resin;
a second region adjacent to the lower surface of the resin; and
a third region between the first and second regions;
wherein a content of the filler in each of the first and second regions is greater than a content of the filler in the third region.

21. The resin composition of claim 20, wherein the filler is not provided in the third region of the resin.

22. A resin coated copper comprising:
an insulating layer; and
a copper foil layer provided on at least one surface of the insulating layer,
wherein the insulating layer includes a resin and a filler disposed in the resin,
wherein the insulating layer includes:
a first region adjacent to an upper surface of the resin;
a second region adjacent to a lower surface of the resin; and
a third region between the first and second regions;
wherein a content of the filler in each of the first and second regions is different from a content of the filler in the third region.

23. The resin coated copper of claim 22, wherein the filler includes at least one concave portion provided on a surface,
wherein a content of the filler has a range of 10 vol. % to 40 vol % of a total volume of the insulating layer,
wherein a porosity corresponds to a volume occupied by the concave portion in a total volume of the filler and has a range of 20% to 35%, and
wherein a dielectric constant (Dk) of the insulating layer including the resin and the filler is 2.5 or less.

24. The resin coated copper of claim 22, wherein the content of the filler in each of the first and second regions is greater than the content of the filler in the third region.

25. The resin coated copper of claim 22, wherein the filler is not provided in the third region of the insulating layer.

26. A circuit board comprising:
an insulating layer;
a circuit pattern disposed on the insulating layer; and
a via passing through the insulating layer;
wherein the insulating layer includes a resin and a filler disposed in the resin,
wherein the insulating layer includes:
a first region adjacent to an upper surface of the resin;
a second region adjacent to a lower surface of the resin; and
a third region between the first and second regions;
wherein a content of the filler in each of the first and second regions is different from a content of the filler in the third region.

27. The circuit board of claim 26, wherein the content of the filler in each of the first and second regions is greater than the content of the filler in the third region.

28. The circuit board of claim 26, wherein The filler is not provided in the third region of the insulating layer.

29. The circuit board of claim 17, wherein the filler includes at least one concave portion provided on a surface,
wherein a content of the filler has a range of 10 vol. % to 40 vol % of a total volume of the insulating layer,
wherein a porosity corresponds to a volume occupied by the concave portion in a total volume of the filler and has a range of 20% to 35%, and
wherein a dielectric constant (Dk) of the insulating layer including the resin and the filler is 2.5 or less.
